(19) United States
(12) Patent Application Publication
(10) Pub. No.: US 2022/0165599 A1
(43) Pub. Date: May 26, 2022

(54) SUBSTRATE PROCESSING APPARATUS

(71) Applicant: SCREEN Holdings Co., Ltd., Kyoto- (JP)

(72) Inventors: Hiroyuki KAWAHARA, Kyoto (JP); Koji HASHIMOTO, Kyoto (JP); Noriyuki KIKUMOTO, Kyoto (JP); Noritake SUMI, Kyoto (JP)

(21) Appl. No.: 17/440,220

(22) PCT Filed: Feb. 26, 2020
(86) PCT No.: PCT/JP2020/007665

§ 371 Date: Sep. 17, 2021

(30) Foreign Application Priority Data
Mar. 25, 2019 (JP) 2019-056627

(51) Int. Cl. H01L 21/677; B08B 3/08; F26B 5/00

(52) U.S. Cl. CPC H01L 21/67745; H01L 21/68707; F26B 5/005; B08B 3/08

(57) ABSTRACT

In a substrate processing apparatus in which a substrate is transported into multiple chambers by using multiple transport mechanisms, while a first transport unit is responsible for the transport of the substrate into the first chamber and the transport of the substrate out from the second chamber, the second transport unit is responsible for the transfer of the substrate from the first chamber to the second chamber. With respect to a transfer zone which is a transport route of the substrate from the first chamber to the second chamber, the first transport unit is arranged above and the second transport unit is arranged below. Since entry into the transfer zone is exclusively allowed, the two transport units can operate individually while avoiding mutual interference.

### TECHNICAL FIELD

The present invention relates to a substrate processing apparatus that performs a predetermined process on a substrate, in particular, to a processing apparatus involving transport of a substrate to a plurality of chambers using a plurality of transport mechanisms.

### BACKGROUND ART

Regarding processes on substrates such as semiconductor substrates, glass substrates, or resin substrates used for manufacturing semiconductor devices, display panels, etc., for example, such processes are generally performed in closed space within a dedicated chamber for the purpose of preventing diffusion of chemicals or controlling atmosphere. Hence, in a substrate processing apparatus where several types of processes are performed continuously on one substrate, the substrate is to be passed between a plurality of chambers.

As a transport mechanism for this passing of a substrate, a transport robot is used, for example. Robots having various configurations have been suggested as the transport robot. For the purpose of increasing the working efficiency of the substrate processing apparatus or for the purpose of holding a substrate in a style responsive to the substance of a process, a plurality of transport mechanisms may be used in combination (see patent literatures 1 and 2, for example).

PTL 1 discloses a substrate processing apparatus for processing the both sides of a substrate by reversing the substrate using a reversing unit. This is achieved by providing a transport robot for transport of a substrate before being reversed and a transport robot for transport of the substrate after being reversed. PTL 2 discloses a substrate processing apparatus where areas are defined by partitions for a plurality of processing steps using different types of processing liquids. A transport robot is provided for each of the areas.

### CITATION LIST

### Patent Literatures

[PTL 1] JP2008-166369A
[PTL 2] JP11-260886A

### SUMMARY OF INVENTION

### Technical Problem

According to the foregoing conventional techniques, while transport routes of transporting a substrate using corresponding transport mechanisms overlap each other partially only in a region for passing of the substrate, these transport routes are basically configured in such a manner as not to overlap each other in a plan view. This tends to result in a large footprint of the apparatus as a whole. To seek further size reduction of the apparatus, an overlap between the transport routes in a plan view is required to extend more widely.

The foregoing conventional techniques cause a plurality of transport mechanisms to operate cooperatively for implementation of a series of processes. Hence, depending on the progress of the processes, some of the transport mechanisms may be kept on standby. To increase throughput of the processes further, an increased margin is required for allowing the transport mechanisms to operate individually.

As described above, in order to increase situations of causing a plurality of transport mechanisms to operate individually while causing transport routes of transporting a substrate using these transport mechanisms to overlap each other, means of preventing interference between the transport mechanisms is required to be devised. However, the foregoing conventional techniques contain no particular mention from this point of view, so that there is still room for improvement in this regard.

The present invention has been made in view of the foregoing problem. In a substrate processing apparatus involving transport of a substrate to a plurality of chambers using a plurality of transport mechanisms, the present invention is intended to provide a technique allowing the transport mechanisms to operate individually with relatively high degrees of freedom while causing transport routes of transporting the substrate using these transport mechanisms to overlap each other.

### Solution to Problem

To achieve the above object, one aspect of a substrate processing apparatus according to the present invention includes: a first chamber with internal space configured to store a substrate as a process target and a first opening for putting the substrate into and taking the substrate out from the internal space; a second chamber with internal space configured to store the substrate and a second opening for putting the substrate into and taking the substrate out from the internal space; a first transport unit with a first holding member for holding the substrate and a first movement mechanism arranged above the first holding member, the first movement mechanism moving the first holding member to transport the substrate into the first chamber through the first opening and to transport the substrate out from the second chamber through the second opening; and a second transport unit with a second holding member for holding the substrate and a second movement mechanism arranged below the second holding member, the second movement mechanism moving the second holding member to transport the substrate out from the first chamber through the first opening and to transport the substrate into the second chamber through the second opening, thereby transferring the substrate from the first chamber to the second chamber.

The first opening and the second opening are formed while bordering transport space where the second transport unit is arranged. With space as part of the transport space defined as a transfer zone where the second holding member and the substrate are to pass through during transfer of the substrate from the first chamber to the second chamber using the second transport unit, the first movement mechanism is configured to locate the first holding member above the transfer zone when the second transport unit accesses the first opening or the second opening, and the second movement mechanism is configured to locate the second holding member below the transfer zone when the first transport unit accesses the first opening or the second opening.

To fulfill the foregoing intention, in another aspect of a substrate processing apparatus according to the present invention, the substrate processing apparatus includes: a first chamber with internal space configured to store a substrate as a process target and a first opening for putting the substrate into and taking the substrate out from the internal space; a second chamber with internal space configured to store the substrate and a second opening for putting the substrate into and taking the substrate out from the internal space; a first transport unit with a first holding member for holding the substrate and a first movement mechanism arranged above the first holding member, the first movement mechanism moving the first holding member to transport the substrate into the first chamber through the first opening and to transport the substrate out from the second chamber through the second opening; a second transport unit with a second holding member for holding the substrate and a second movement mechanism arranged below the second holding member, the second movement mechanism moving the second holding member to transport the substrate out from the first chamber through the first opening and to transport the substrate into the second chamber through the second opening, thereby transferring the substrate from the first chamber to the second chamber; and a controller that controls the first transport unit and the second transport unit.

The first opening and the second opening are formed while bordering transport space where the second transport unit is arranged. With space as part of the transport space defined as a transfer zone where the second holding member and the substrate are to pass through during transfer of the substrate from the first chamber to the second chamber using the second transport unit, the controller restricts entry of the first holding member into the transfer zone when the second transport unit accesses the first opening or the second opening, and restricts entry of the second holding member into the transfer zone when the first transport unit accesses the first opening or the second opening.

According to the invention having the foregoing configuration, the first transport unit and the second transport unit each having the function as the “transport mechanism” described above realizes transport of the substrate to and from a plurality of chambers. More specifically, the substrate is first transported to the first chamber, then transferred to the second chamber, and finally, transported out from the second chamber. Out of these, the first transport unit is responsible for the transport of the substrate into the first chamber and the transport of the substrate out from the second chamber. The second transport unit is responsible for the transfer of the substrate from the first chamber to the second chamber. Thus, the first holding member is also to enter the transfer zone, if necessary, which is a route used by the second holding member when the second transport unit transfers the substrate from the first chamber to the second chamber.

In the configuration having the two transport units, these transport units may interfere with each other in accessing to the first chamber and the second chamber. In this regard, according to the present invention, in the first transport unit, the first movement mechanism of the first transport unit that moves the first holding member for holding the substrate is arranged above the first holding member. On the other hand, in the second transport unit, the second movement mechanism that moves the second holding member is arranged below the second holding member.

The first movement mechanism and the first holding member may be coupled directly or may be coupled through an appropriate coupling member. The configuration of this coupling using the coupling member can be such that one end of the coupling member is coupled to a specific portion on the upper surface or a side surface of the first holding member, and the other end of the coupling member is coupled to the first movement mechanism. The coupling is made in such a manner that any part of the coupling member is located at the same height as or above the lower end of the first holding member.

Likewise, the second movement mechanism and the second holding member may be coupled directly or may be coupled through an appropriate coupling member. The configuration of this coupling using the coupling member can be such that one end of the coupling member is coupled to a specific position on the upper surface or a side surface of the second holding member, and the other end of the coupling member is coupled to the second movement mechanism. The coupling is made in such a manner that any part of the coupling member is located at the same height as or above the lower end of the second holding member.

While the first transport unit allows the first holding member to enter the transfer zone from above the transfer zone, the second transport unit allows the second holding member to enter the transfer zone from below the transfer zone. Specifically, a movement route for the first holding member is defined above the transfer zone between the first chamber and the second chamber and a movement route for the second holding member is defined below the transfer zone. This allows the movement route for the first holding member and the movement route for the second holding member to overlap each other largely in a plan view.

In the transfer zone where interference between the first holding member and the second holding member is likely to occur, only one of these holding members enters the transfer zone selectively and entries of both of these holding members into the transfer zone are avoided. In a spatial region except the transfer zone, causing the first transport unit and the second transport unit to operate independently of each other does not result in mutual interference.

### Advantageous Effects of Invention

As described above, according to the present invention, the first transport unit and the second transport unit, each configured to access the first chamber and the second chamber to transport the substrate, are to move along the respective movement routes defined above and below the transfer zone between the first chamber and the second chamber. This causes the movement routes for these transport units to overlap each other largely in a plan view, thereby allowing footprint reduction of the apparatus. As only one of the first transport unit and the second transport unit is allowed to enter the transfer zone, it becomes possible to prevent interference between the transport units reliably in the transfer zone and to allow the transport units to operate independently of each other while not being restricted by the other in a zone except the transfer zone.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF DRAWINGS

FIG. 1 is a plan view showing the entire configuration of an embodiment of the substrate processing apparatus according to the present invention.

FIG. 2 is a side view schematically showing the configuration of one processing unit.

FIG. 3 is a side view schematically showing the configuration of one processing unit.

FIG. 4 is a block diagram showing the configuration of a control system of the substrate processing apparatus.

FIG. 5 is a flowchart showing the outline of a procedure taken in the substrate processing apparatus.

FIG. 6 is a drawing schematically showing a transport route of a substrate in the substrate processing apparatus.

FIG. 7 is a drawing schematically showing a transport route of a substrate in the substrate processing apparatus.

FIG. 8 is a drawing schematically showing a transport route of a substrate in the substrate processing apparatus.

FIG. 9A is a drawing schematically showing a transport route of a substrate in the substrate processing apparatus.

FIG. 9B is a drawing schematically showing a transport route of a substrate in the substrate processing apparatus.

FIG. 10A is a drawing showing a modification of the hand of the wet transport robot.

FIG. 10B is a drawing showing a modification of the hand of the wet transport robot.

### DESCRIPTION OF EMBODIMENTS

An embodiment of a substrate processing apparatus according to the present invention will be described below. The substrate processing apparatus is a processing apparatus for performing a wet process on a substrate transported into the apparatus from outside, and then drying and transporting the substrate out from the apparatus. The substrate processing apparatus is applicable preferably to the purpose of performing wet cleaning on a substrate using an appropriate cleaning liquid and then performing a drying process using a supercritical fluid, for example. In an example described below, a series of processes performed on a substrate by the substrate processing apparatus include a wet cleaning process and a supercritical drying process. However, the layout of the apparatus and the configuration of each unit described below are applicable not only to such processes but are also applicable to various types of processes.

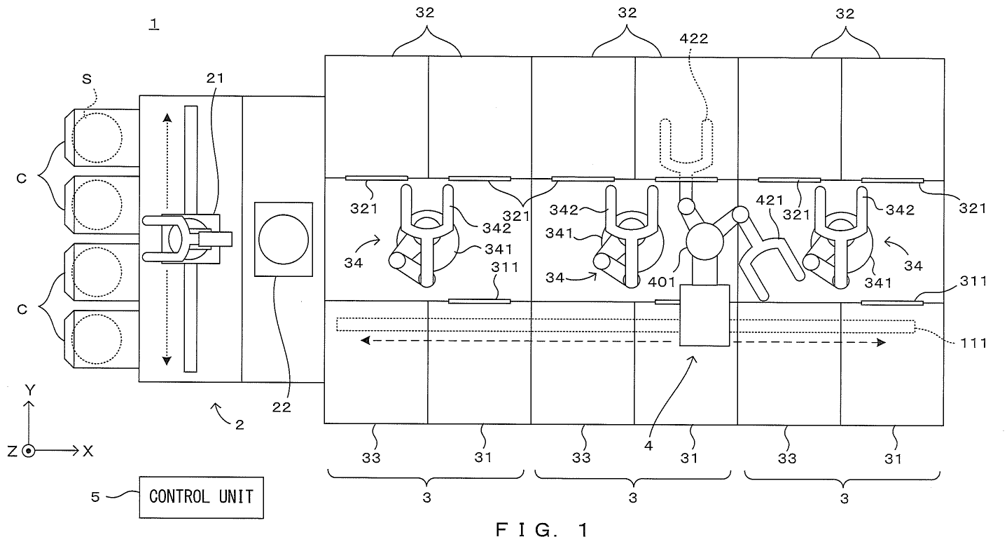

FIG. 1 is a plan view showing the entire configuration of an embodiment of the substrate processing apparatus according to the present invention. A substrate processing apparatus 1 includes an indexer unit 2, one or a plurality of (in this example, three) processing units 3, a dry transport robot 4, and a control unit 5 as principal structures. To show directions in the drawings referred to below in a unified manner, XYZ orthogonal coordinate axes are set as shown in FIG. 1. The XY plane represents a horizontal plane. The Z axis represents a vertical axis, more specifically, a (−Z) direction represents a vertically downward direction.

The indexer unit 2 includes an indexer robot 21 and a passing stage 22. The indexer unit 2 has a side surface on the (−X) side to which one or a plurality of cassettes C storing a plurality of substrates S is attachable. The indexer robot 21 takes unprocessed substrates S one by one from the cassette C and places the substrates S taken out onto the passing stage 22. The indexer robot 21 stores the substrate S on the passing stage 22 after being processed in the processing unit 3 into the cassette C. As shown by dotted lines with arrow heads in the drawing, the indexer robot 21 is movable in the Y direction for access to each cassette C.

The substrate processing apparatus 1 of this example includes three processing units 3 aligned in the X direction. These processing units 3 have the same configuration and fulfill the same function. Each of the processing units 3 includes a cleaning chamber 31, drying chambers 32, 32, a fluid box 33, and a wet transport robot 34. The cleaning chamber 31 accepts the substrate S in internal space thereof and performs a cleaning process. The drying chamber 32 accepts the cleaned substrate S and performs a drying process. The fluid box 33 stores various types of processing fluids used for these processes. The wet transport robot 34 transfers the substrate S cleaned by the cleaning chamber 31 to the drying chamber 32 for implementation of the drying process.

More specifically, the cleaning chamber 31 of a box shape has a side surface on the (+Y) side where an opening 311 is formed, and the substrate S is put into and taken out through the opening 311. In the cleaning chamber 31, the substrate S is subjected to the cleaning process using an appropriate cleaning liquid (for example, pure water or deionized water), and a replacement process of replacing the cleaning liquid remaining on a surface of the substrate S after the cleaning with a fluid of lower surface tension such as isopropyl alcohol (IPA), for example.

If the substrate S has a surface provided with a fine pattern, drying the cleaned substrate S as it is may cause collapse of the pattern due to the surface tension of the cleaning liquid. This problem can be avoided by replacing the cleaning liquid with a fluid of lower surface tension and then drying the substrate S. The cleaning process, the replacement process, and the configurations of devices or those of chambers used for these processes are publicly known, so that they will be not explained in this description.

The substrate S is transported by the wet transport robot 34 out from the cleaning chamber 31 while a liquid film of the low surface tension fluid is formed on a surface of the substrate S and the substrate S is in a horizontal posture. The wet transport robot 34 has a hand 342 rotatable about the vertical axis and expansible and contractible in the horizontal direction relative to a robot body 341. The hand 342 moves while holding the lower surface of the substrate S to transport the substrate S. For example, providing a suction mechanism not shown in the drawings to the hand 342 allows the substrate S to be held reliably. After the substrate S is transported out from the cleaning chamber 31, the substrate S is transported into one of the drying chambers 32.

The drying chamber 32 of a box shape has a side surface on the (−Y) side where an opening 321 is formed. The substrate S is put into and taken out through the opening 321. In the drying chamber 32, the substrate S with the liquid film formed on its surface is subjected to the drying process of removing the liquid film and drying the substrate. If an extremely fine pattern is formed on the surface of the substrate, it may be impossible to find or difficult to obtain a suitable substance having surface tension low enough for preventing collapse of the pattern and available as a liquid at normal temperature and normal pressure.

The supercritical drying process may be used as the drying process applicable to such a case. While the principles of this process are publicly known so will not be described in detail, the supercritical drying process is to replace a liquid remaining on the substrate S and dry the substrate S by taking advantage of the extremely low surface tension of a substance turned into a supercritical fluid under high temperature and high pressure. A substance available for this purpose is carbon dioxide to be put into a supercritical state under relatively low temperature and relatively low pressure, for example. Further, the carbon dioxide in the supercritical state has high solubility in an organic solvent such as IPA or acetone, so that it is used preferably as a fluid for replacing these solvents.

After the substrate S with the liquid film is transported into the drying chamber 32, carbon dioxide is introduced into the drying chamber 32 in an airtight condition to apply predetermined temperature and pressure to the drying chamber 32. By doing so, the carbon dioxide turned into a supercritical fluid replaces the liquid film on the surface of the substrate S. Then, a pressure in the chamber is reduced to cause volatilization of the carbon dioxide, thereby putting the substrate S into a dried state. Vaporizing the carbon dioxide directly from the supercritical state avoids the occurrence of a vapor-liquid interface to cause pattern collapse. This allows drying of the substrate S without causing collapse of a fine pattern.

The fluids used in the corresponding processes described above that specifically include the cleaning liquid, the organic solvent, carbon dioxide and the like are supplied from the fluid box 33 provided in each processing unit 3 to the cleaning chamber 31 and to the drying chamber 32. In this example, in order to enhance the working efficiency of each chamber in response to time required for the process in this chamber, one cleaning chamber 31 and two drying chambers 32 are provided in combination in each processing unit 3. However, as long as at least one cleaning chamber and at least one drying chamber are provided, the number of combined chambers is determined freely. The fluid box for the cleaning process and the fluid box for the drying process may be provided separately. Alternatively, one fluid box may be provided for a plurality of processing units.

An unprocessed substrate is transported into each processing unit 3 and a processed substrate is transported out from each processing unit 3 by the dry transport robot 4. The dry transport robot 4 includes a robot body 401 horizontally movable along a guiderail 111 extending in the X direction, and hands 421 and 422 provided at a lower part of the robot body 401. Each of the hands 421 and 422 is rotatable about the vertical axis and expansible and contractible in the horizontal direction relative to the robot body 401. The substrate S can be moved in response to movements of these parts holding the lower surface of the substrate S. The two hands 421 and 422 are used separately in response to the state of a substrate to be held. Specifically, the hand 421 is used for holding an unprocessed substrate, and the hand 422 is used for holding a processed substrate.

The substrate S is transported by a combination of the movement of the robot body 401 in the X direction and the movement of the hand 421 or 422 relative to the robot body 401. More specifically, an unprocessed substrate S placed on the passing stage 22 is held by the hand 421, and is transported into the cleaning chamber 31 of any of the processing units 3. After the substrate S is subjected to the drying process in any of the drying chambers 32, the processed substrate S is held by the hand 422 and transported out from the drying chamber 32, and then transported to the passing stage 22.

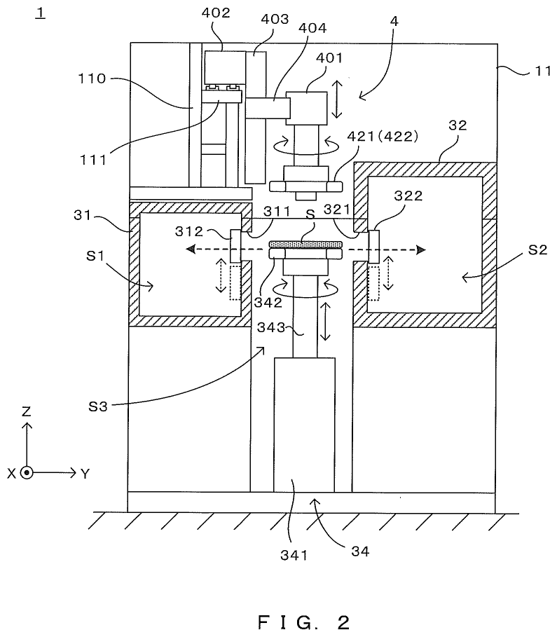

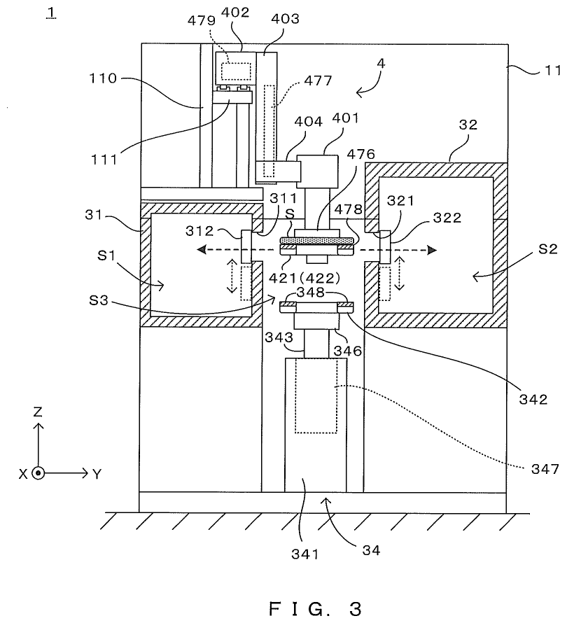

FIGS. 2 and 3 are side views each schematically showing the configuration of one processing unit. FIG. 2 shows a state where the wet transport robot 34 accesses a chamber, and FIG. 3 shows a state where the dry transport robot 4 accesses the chamber. To increase the viewability of the drawings, only one hand of the dry transport robot 4 is illustrated. Illustrations of structures inside the chamber are also omitted.

As shown in FIG. 2, in the substrate processing apparatus 1, the cleaning chamber 31 is provided on the (−Y) side of a housing 11 forming the outline of the apparatus, and the opening 311 is formed on the side surface on the (+Y) side of the cleaning chamber 31. An open/close shutter 312 is attached to the opening 311. The closed state of the shutter 312 (indicated by solid lines) brings chamber internal space S1 into an airtight condition. The open state of the shutter 312 (indicated by dotted lines) allows putting in and taking out of the substrate S through the opening 311.

The drying chamber 32 is provided on the (+Y) side of the housing 11, and the opening 321 is formed on the side surface on the (−Y) side of the drying chamber 32. An open/close shutter 322 is attached to the opening 321. The closed state of the shutter 322 (indicated by solid lines) brings chamber internal space S2 into an airtight condition. The open state of the shutter 322 (indicated by dotted lines) allows putting in and taking out of the substrate S through the opening 321. In this way, the cleaning chamber 31 and the drying chamber 32 are arranged in the housing 11 in such a manner that the respective openings 311 and 321 face each other across space where the wet transport robot 34 is arranged (hereinafter called “transport space”) S3.

Regarding the wet transport robot 34, the robot body 341 is fixed to the bottom of the housing 11 in the transport space S3 sandwiched between the cleaning chamber 31 and the drying chamber 32. An elevating shaft 343 configured to move up and down extends upward from the robot body 341, and the hand 342 is attached to an upper part of the elevating shaft 343. The substrate S is transported by means of a combination of rotation of the hand 342 about the vertical axis and movement of the hand 342 in the horizontal direction in response to its expansion and contraction.

More specifically, as shown in FIG. 2, while the hand 342 holding the substrate S is located at a position corresponding to the height of the opening 311 of the cleaning chamber 31, the hand 342 moves horizontally toward the (−Y) direction from a center position shown in the drawing, thereby realizing entry into and retreat from the internal space S1 of the cleaning chamber 31. Also, while the hand 342 is located at a position corresponding to the height of the opening 321 of the drying chamber 32, the hand 342 moves horizontally toward the (+Y) direction from the center position, thereby realizing entry into and retreat from the internal space S2 of the drying chamber 32.

As shown in FIG. 3, as the configuration to enable this movement, the wet transport robot 34 includes a hand driving mechanism 346 for rotating, expanding, and contracting the hand 342, an elevating mechanism 347 for moving up and down the elevating shaft 343 supporting the hand 342, a suction mechanism 348 for holding the substrate S under suction using the hand 342, etc.

While each of these structures is not illustrated in detail in the drawings, the hand driving mechanism 346 includes a rotary motor for rotating the hand 342, and a horizontal movement mechanism with a motor and a rack-and-pinion mechanism for moving the hand 342 horizontally, for example. The suction mechanism 348 includes a contact part to contact the substrate S and used for sucking the substrate S, a pump for applying suction force to the contact part, and a pipe connecting the contact part and the pump to each other, for example.

If the opening 311 of the cleaning chamber 31 and the opening 321 of the drying chamber 32 are aligned at the same opening height, only the horizontal movement of the hand 342 is required for transferring the substrate S from the cleaning chamber 31 to the drying chamber 32. In particular, regarding the substrate S with the liquid film formed on its upper surface, requiring only the horizontal movement like in this case for completing the transfer works advantageously in terms of retaining the liquid film.

The wet transport robot 34 to transfer the substrate W with the liquid film is required to have corrosion resistance against a chemical substance to be used and drip-proof properties for preventing entry of a liquid dropping from the substrate S into the wet transport robot 34. In the present embodiment, as pure water or DIW is used as a cleaning liquid and IPA of relatively low corrosiveness is used for liquid film formation, high corrosion resistance becomes unnecessary.

The dry transport robot 4 is movable in the X direction. More specifically, the guiderail 111 extending in the X direction is attached to a frame 110 fixed to the housing 11. The dry transport robot 4 is attached to the guiderail 111 in such a manner as to be capable of traveling in the X direction. The dry transport robot 4 includes a traveling block 402 engaged with the guiderail and to travel in the X direction, a boom member 403 extending downward from the traveling block 402, and an elevating member 404 attached to the boom member 403 in such a manner as to be movable up and down.

The robot body 401 is attached to the elevating member 404 and is to move up and down together with the elevating member 404. The hand 421 (422) is attached to a lower part of the robot body 401. The robot body 401 rotates the hand 421 (422) about the vertical axis and moves the hand 421 (422) horizontally.

As shown in FIG. 3, as the configuration to enable this movement, the dry transport robot 4 includes a hand driving mechanism 476, an elevating mechanism 477, a suction mechanism 478, a traveling mechanism 479, etc. The hand driving mechanism 476 rotates, expands, and contracts the hands 421 and 422. The elevating mechanism 477 moves the elevating member 404 up and down to move the hands 421 and 422 up and down together with the robot body 401. The suction mechanism 478 holds the substrate S under suction using the hands 421 and 422. The traveling mechanism 479 causes the traveling block 402 to travel in the X direction.

While each of these structures is not illustrated in detail in the drawings, the hand driving mechanism 476 includes a plurality of rotary motors for rotating corresponding ones of the hands 421 and 422, and a horizontal movement mechanism with a motor and a rack-and-pinion mechanism for moving the hands 421 and 422 horizontally, for example. The elevating mechanism 477 includes a plurality of elevating shafts for moving the hands 421 and 422 up and down, and a motor and a rack-and-pinion mechanism for moving these elevating shafts up and down, for example. The suction mechanism 478 includes a contact part to contact the substrate S and used for sucking the substrate S, a pump for applying suction force to the contact part, and a pipe connecting the contact part and the pump to each other, for example. The traveling mechanism 479 includes a motor and a rack-and-pinion mechanism for causing the traveling block 402 to travel in the X direction, for example.

As shown in FIG. 2, when the wet transport robot 34 accesses the cleaning chamber 31 or the drying chamber 32, the robot body 401 is retreated upward. This prevents the hand 421 (422) from interfering with the operation of the wet transport robot 34. On the other hand, as shown in FIG. 3, as the robot body 401 moves down until the hand 421 (422) reaches the same height as the openings 311 and 321, the hand 421 (422) becomes accessible to the cleaning chamber 31 or the drying chamber 32. In this case, the wet transport robot 34 retreats the hand 342 downward to prevent interference with the dry transport robot 4.

The dry transport robot 4 is responsible for the function of transporting an unprocessed substrate S into the cleaning chamber 31 and the function of transporting the substrate S after being subjected to the drying process out from the drying chamber 32. This means that the handled substrates S are both in a dried state. Further, the dry transport robot 4 is arranged above the wet transport robot 34 which handles a wet substrate W. This makes it unlikely that liquid dropping from the substrate S will adhere to the dry transport robot 4. For this reason, the hands 421 and 422, and the robot body 401 are not required to have high drip-proof properties.

However, there is a risk of dissipation of vapor of a chemical substance used in a process into an atmosphere in the space S3 and exposure to the dissipated vapor. Thus, corrosion resistance of a degree enough for resisting such vapor is preferably provided. Furthermore, as an unprocessed substrate S and a processed substrate S have different levels of cleanness, these substrates S are preferably handled by different hands. In this way, required specifications differ between a case of transporting an unprocessed substrate or a processed substrate S in a dried state and a case of transporting a substrate S in a wet state on which a liquid film is formed. In response to this, the dry transport robot 4 and the wet transport robot 34 conforming to the respective modes of transport are used in combination.

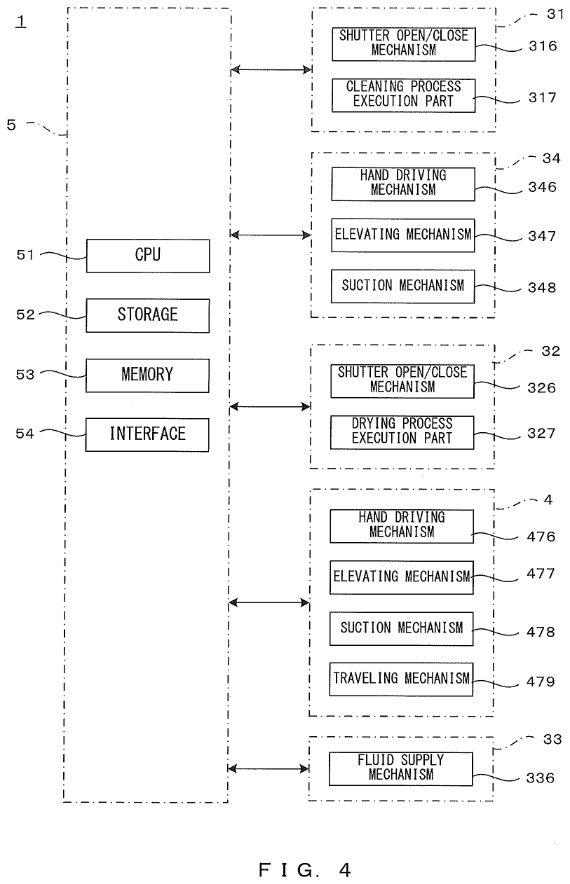

FIG. 4 is a block diagram showing the configuration of a control system of the substrate processing apparatus. The control unit 5 for control over the operation of the substrate processing apparatus 1 includes a central processing unit (CPU) 51 to execute a control program prepared in advance. Each unit of the substrate processing apparatus 1 described above operates on the basis of the control program executed by the CPU 51. The control unit 5 further includes a storage 52 storing the control program to be executed by the CPU 51, various types of set data, etc. on a long-term basis, a memory 53 temporarily storing data necessary for execution of the control program by the CPU 51, and an interface 54 for information exchange with an external device or an operator, for example. Each of these structures can be substantially the same as hardware provided in a general personal computer. Specifically, providing an appropriate control program makes a personal computer having publicly-known structures available as the control unit 5.

The following briefly describes structures in each unit controlled by the control unit 5. The cleaning chamber 31 is provided with a shutter open/close mechanism 316 for driving the shutter 312 at the opening 311 to open and close, and a process execution part 317 to perform the cleaning process according to a predetermined processing recipe. These parts operate in response to a control command from the control unit 5. Likewise, the drying chamber 32 is provided with a shutter open/close mechanism 326 for driving the shutter 322 to open and close, and a process execution part 327 to perform the drying process according to a predetermined processing recipe. These parts operate in response to a control command from the control unit 5.

In the wet transport robot 34, the hand driving mechanism 346, the elevating mechanism 347, the suction mechanism 348, etc. operate in response to a control command from the control unit 5. In the dry transport robot 4, the hand driving mechanism 476, the elevating mechanism 477, the suction mechanism 478, the traveling mechanism 479, etc. operate in response to a control command from the control unit 5.

Furthermore, the fluid box 33 is provided with a fluid supply mechanism 336 that supplies various types of fluids to be used for the processes by the cleaning chamber 31 and the drying chamber 32 to the corresponding chambers, and the fluid supply mechanism 336 operates in response to a control command from the control unit 5.

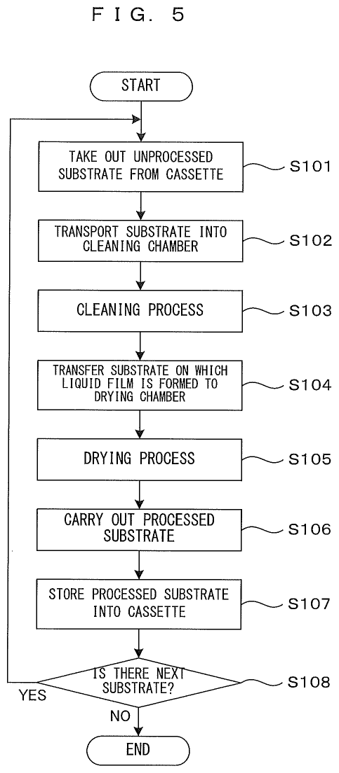

FIG. 5 is a flowchart showing the outline of a procedure taken in the substrate processing apparatus. This procedure is realized by causing the CPU 51 of the control unit 5 to execute the control program prepared in advance and causing each unit of the apparatus to perform predetermined operation. This procedure is started while at least one cassette C storing unprocessed substrates S is attached to the substrate processing apparatus 1.

First, one unprocessed substrate S is taken out from the cassette C (step S101). More specifically, the indexer robot 21 takes the substrate S out from one cassette C and places the substrate S taken out onto the passing stage 22.

The substrate S is transported into the cleaning chamber 31 by the dry transport robot 4 (step S102). More specifically, the dry transport robot 4 moves along the guiderail 111 to an end of the guiderail 111 on the (−X) side, and holds the substrate S on the passing stage 22 using the hand 421. In this state, the dry transport robot 4 moves in the (+X) direction and is located at a position near any of the cleaning chambers 31. Then, the hand 421 enters the internal space S1 of the cleaning chamber 31 with the opened shutter 311, and transports the substrate S into the cleaning chamber 31.

In the cleaning chamber 31, the incoming substrate S is subjected to the cleaning process (step S103). More specifically, a cleaning liquid from the fluid supply mechanism 336 of the fluid box 33 is supplied to the substrate S to clean the substrate S. Then, IPA is supplied as a low surface tension fluid of lower surface tension than the cleaning liquid onto a surface of the substrate S, thereby forming a liquid film.

Then, the substrate S with the resultant liquid film is transferred from the cleaning chamber 31 to the drying chamber 32 (step S104). Specifically, the hand 342 of the wet transport robot 34 enters the cleaning chamber 31 with the opened shutter 312, and transports the substrate S with the liquid film out from the cleaning chamber 31 while holding the substrate S in a horizontal posture. Furthermore, the hand 342 enters the drying chamber 32 with the opened shutter 322, and transports the substrate S into the internal space S2 of the drying chamber 32.

In the drying chamber 32, the incoming substrate S is subjected to the drying process (step S105). More specifically, the shutter 322 is closed and the internal space S2 is brought to an airtight condition. Then, carbon dioxide in a liquid phase is introduced into the internal space SP. The carbon dioxide as liquid dissolves IPA well forming the liquid film on the substrate S, so that the IPA is replaced with the carbon dioxide on the substrate S. Furthermore, the interior of the chamber is adjusted to predetermined temperature and pressure to turn the carbon dioxide into a supercritical fluid. By reducing pressure in the chamber rapidly from this state, the carbon dioxide in the supercritical state is vaporized without passing through a liquid phase to be removed from the surface of the substrate S. As the supercritical fluid penetrating into a fine pattern is removed without forming a vapor-liquid interface, the substrate S can be dried without causing collapse of the pattern.

After being subjected to the drying process, the substrate S is transported out from the drying chamber 32 (step S106), and stored into the cassette C (step S107). More specifically, the hand 422 of the dry transport robot 4 enters the internal space S2 of the drying chamber 32 through the opening 321, and transports the processed substrate S out from the drying chamber 32. The dry transport robot 4 moves horizontally in the (−X) direction, and places the substrate S onto the passing stage 22. The substrate S is stored into the cassette C by the indexer robot 21. In this way, the processes on one substrate S are completed.

In the presence of an unprocessed substrate S to be processed subsequently (YES in step S108), the procedure returns to step S101 and processes same as those described above are repeated on the different unprocessed substrate S stored in the cassette C. If the processes on all the substrates S to be processed are finished (NO in step S108), the procedure is finished.

As a result of implementation of the foregoing processes by each of the processing units 3, the processes can be performed simultaneously on a plurality of substrates S. Furthermore, all the foregoing processing steps can be performed in parallel in one processing unit 3. For example, during implementation of the drying process on one substrate S in the drying chamber 32, the cleaning process can be performed on a different substrate S in the cleaning chamber 31. As another example, while the wet transport robot 34 takes the substrate S out from the cleaning chamber 31, a substrate S to be processed next can be transported by the dry transport robot 4. By processing a plurality of substrates S efficiently using a combination of the processes in each chamber and transports using the transport robots in this way, it becomes possible to seek throughput increase in the processes.

A problem to be caused in realizing such operation is interference between the transport robots. Specifically, during each of the foregoing operations of transporting the substrate S using the wet transport robot 34 and transporting the substrate S using the dry transport robot 4, access to the cleaning chamber 31 is made through the opening 311. Also, access to the drying chamber 32 is made through the opening 321. For this reason, transport routes of transporting the substrate S using the two transport robots 34 and 4 overlap each other, particularly around the chamber openings 311 and 321. Hence, if the wet transport robot 34 and the dry transport robot 4 operate independently of each other, interference is likely to occur at an overlap of the transport routes. In the present embodiment, a solution to this problem is sought by the following configuration.

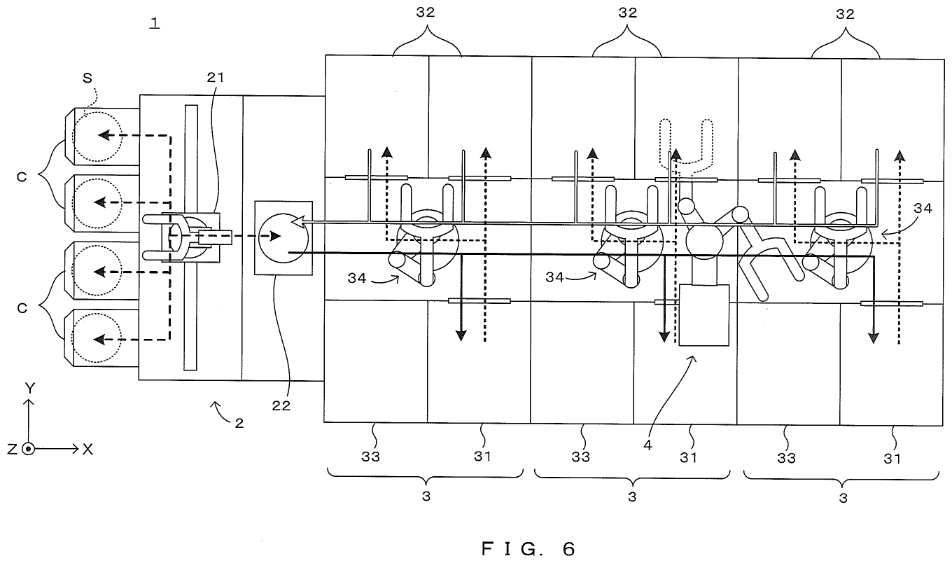

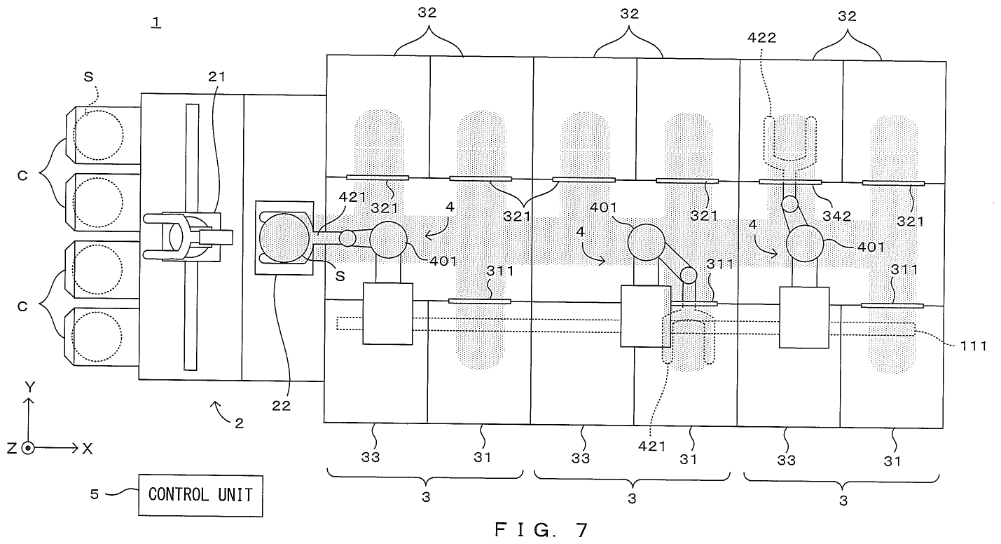

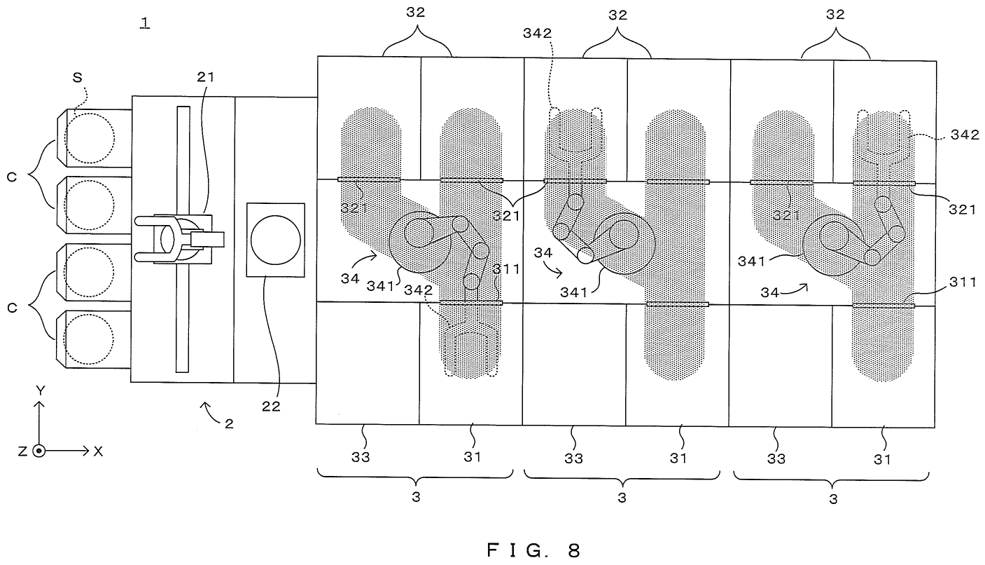

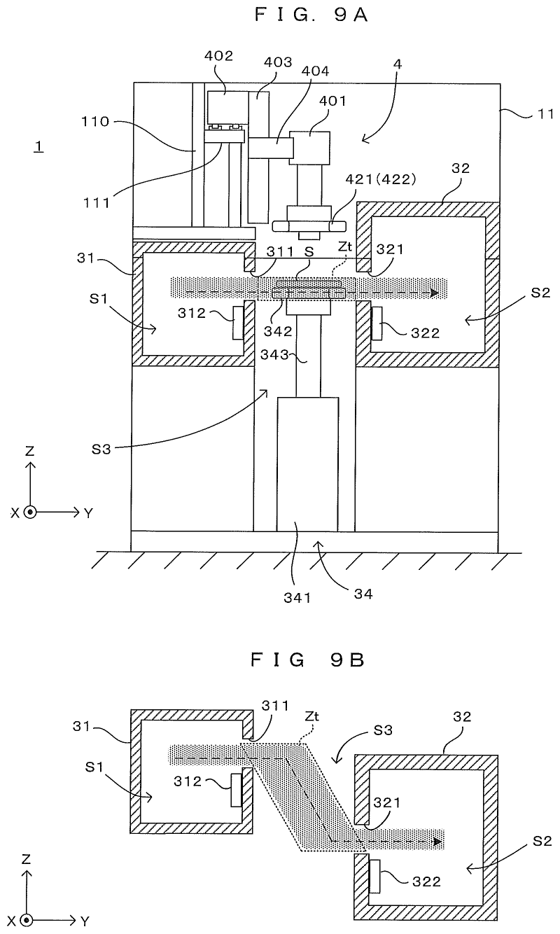

FIGS. 6, 7, 8, 9A, and 9B each schematically show a transport route of transporting a substrate in the substrate processing apparatus. More specifically, FIG. 6 schematically shows a route of transporting the substrate S transported by the indexer robot 21, the wet transport robot 34, and the dry transport robot 4. FIG. 7 is a plan view showing space where the hands 421 and 422 and the substrate S are to pass through during transport of the substrate S by the dry transport robot 4. FIG. 8 is a plan view showing space where the hand 342 and the substrate S are to pass through during transport of the substrate S by the wet transport robot 34. FIGS. 9A and 9B are side views showing this space. In these drawings, to facilitate viewability of the drawings, illustrations of some of the structures not related directly to the description or additions of reference signs to such structures are omitted.

As indicated by dashed lines with arrow heads in FIG. 6, the indexer robot 21 is responsible for transport of the substrate S from each cassette C to the passing stage 22 and transport of the substrate S from the passing stage 22 to the cassette C. As indicated by solid lines with arrow heads, the dry transport robot 4 transports an unprocessed substrate S from the passing stage 22 to each cleaning chamber 31. As indicated by blank lines with an arrow head, the dry transport robot 4 transports a processed substrate S from each drying chamber 32 to the passing stage 22. As indicated by dotted lines with arrow heads, the wet transport robot 34 is responsible for transport of the substrate S from the cleaning chamber 31 to the drying chamber 32 in each processing unit 3. In this case, the substrate S to be transported has a liquid film made of IPA formed on its upper surface.

FIGS. 7, 8, 9A, and 9B each show a path of space with dots occupied by the hands and the substrate during the course of the transport described above. Three dry transport robots 4 are illustrated in FIG. 7. Each of the dry transport robots 4 illustrates the dry transport robot 4 in a state of accessing the passing stage 22, the dry transport robot 4 in a state of accessing one cleaning chamber 31, and the dry transport robot 4 in a state of accessing one drying chamber 32, respectively. For the convenience of illustration, these three states are illustrated in one drawing. As described above, one dry transport robot 4 is provided for the three processing units 3.

As understood from a comparison between FIGS. 7 and 8, a transport route of transporting the substrate S using the wet transport robot 34 and a transport route of transporting the substrate S using the dry transport robot 4 overlap each other in large part in a plan view. This results in the advantage of footprint reduction of the apparatus achieved by the overlap between the transport routes. On the other hand, not preparing separate transport routes causes the risk of interference by simultaneous entries of the two transport robots into the same space.

In the present embodiment, while size reduction of the apparatus is sought by encouraging an overlap between transport routes in a plan view, the transport routes are separated in the vertical direction to prevent interference between the two types of transport robots. FIG. 9A shows a spatial region with dots where the substrate S and the hand 342 are to pass through when the wet transport robot 34 transfers the substrate S from the cleaning chamber 31 to the drying chamber 32. Out of this spatial region, a region included in the transport space S3 (a region surrounded by dotted lines) is defined as a transfer zone Zt.

The transfer zone Zt is also a spatial region where the hands 421 and 422 are to enter during transport of the substrate S into the cleaning chamber 31 by the dry transport robot 4 and during transport of the substrate S out from the drying chamber 32 by the dry transport robot 4. The hand 342 of the wet transport robot 34 moves up and down between the transfer zone Zt and a retreat position below the transfer zone Zt. On the other hand, each of the hands 421 and 422 of the dry transport robot 4 moves up and down between the transfer zone Zt and a retreat position above the transfer zone Zt. Thus, as long as simultaneous entries of these transport robots into the transfer zone Zt are avoided, no interference occurs between these transport robots.

More specifically, the following rule may be established for control of the wet transport robot 34 and the dry transport robot 4 by the control unit 5. This rule is that, while the hand of one of the transport robots is in the transfer zone Zt, entry of the hand of the other transport robot into the transfer zone Zt is to be restricted. As long as this rule is followed, entries of the dry transport robot 4 and the wet transport robot 34 into the transfer zone Zt are permitted exclusively. As a result, even if the wet transport robot 34 and the dry transport robot 4 operate individually, interference between these robots is still avoided.

When the dry transport robot 4 moves in the X direction, the position of each of the hands 421 and 422 in a vertical direction is set to be higher than the transfer zone Zt. This causes each of the hands 421 and 422 to pass through over the wet transport robot 34, thereby avoiding interference between the robots. Thus, it becomes possible to set an operation sequence by which transfer of the substrate S from the cleaning chamber 31 to the drying chamber 32 using the wet transport robot 34 and transfer of the substrate S in the X direction using the dry transport robot 4 are to be done simultaneously, for example.

Note that this idea is further applicable to a case where the opening 311 of the cleaning chamber 31 and the opening 321 of the drying chamber 32 are not arranged at the same height. Specifically, as shown in FIG. 9B, the opening 311 of the cleaning chamber 31 and the opening 321 of the drying chamber 32 may be at different positions in the vertical direction. In this case, while the transfer zone Zt shown with dots indicating paths of movements of the substrate S and the hand 342 takes a more complicated shape than the foregoing shape, such a shape can be defined in the same way.

The hand of only one of the transport robots is caused to enter this transfer zone Zt selectively. This achieves an operation sequence allowing prevention of interference between the transport robots. More safely, the hands of the two transport robots are selectively caused to enter a spatial region covering the transfer zone Zt and wider than the transfer zone Zt like a region surrounded by dotted lines in FIG. 9B. By doing so, interference between the transport robots is prevented more reliably.

As described above, in the foregoing embodiment, the cleaning chamber 31 functions as a “first chamber” of the present invention, and the opening 311 corresponds to a “first opening” of the present invention. The drying chamber 32 functions as a “second chamber” of the present invention, and the opening 321 corresponds to a “second opening” of the present invention.

In the foregoing embodiment, the dry transport robot 4 functions as a “first transport unit” of the present invention. The hands 421 and 422 function as a “first holding member” of the present invention, the hand driving mechanism 476 and the elevating mechanism 477 function as a “first movement mechanism” of the present invention, and the traveling mechanism 479 functions as a “horizontal movement mechanism” of the present invention. On the other hand, the wet transport robot 34 functions as a “second transport unit” of the present invention. The hand 342 functions as a “second holding member” of the present invention, and the hand driving mechanism 346 and the elevating mechanism 347 function as a “second movement mechanism” of the present invention. The control unit 5 functions as a “controller” of the present invention.

Note that the invention is not limited to the above embodiment and various changes other than the aforementioned ones can be made without departing from the gist of the invention. Regarding the wet transport robot 34 of the foregoing embodiment, for example, this robot 34 transports the substrate S with a liquid film formed on its surface in the cleaning chamber 31 to the drying chamber 32 while maintaining the substrate S in a horizontal posture. However, in the drying process using a supercritical fluid, for example, a configuration suggested for this process is such that a substrate having been transported with a liquid film formed thereon is turned upside down before being transported into the drying chamber. Process configured in this way can be realized by changing part of the configuration of the foregoing wet transport robot as follows.

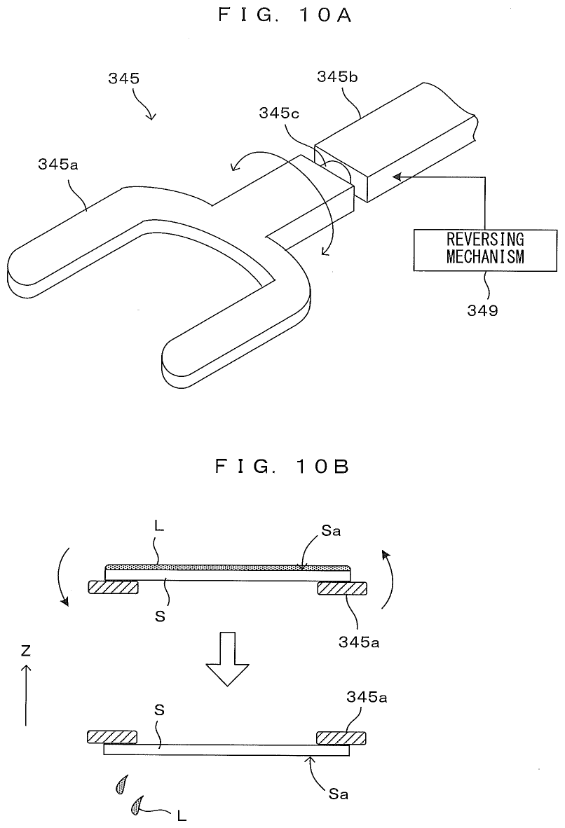

FIGS. 10A and 10B each show a modification of the hand of the wet transport robot. As shown in FIG. 10A, a hand 345 of this modification is available instead of the hand 342 of the wet transport robot 34 of the foregoing embodiment. The hand 345 includes a tip part 345a for holding the substrate S and a base part 345b as separate parts connected to each other through a joint 345c. This makes the tip part 345a rotatable relative to the base part 345b. The wet transport robot 34 further includes a reversing mechanism 349. As the reversing mechanism 349 operates in response to a control command from the control unit 5, the tip part 345a rotates in a direction indicated by arrows shown in FIG. 10A.

As shown in FIG. 10B, the hand 345 holds a substrate W under suction having an upper surface Sa on which a liquid film L is formed in the cleaning chamber 31, and transports the substrate W out from the cleaning chamber 31 while maintaining the substrate W in a horizontal posture. The reversing mechanism 349 turns the tip part 345a upside down immediately before the substrate S is transported into the drying chamber 32. By doing so, the upper surface Sa of the substrate S on which the liquid film L is formed is turned into a lower surface to cause a liquid forming the liquid film to fall down. Immediately thereafter, the substrate S is transported to the drying chamber 32 and subjected to the drying process.

While much of the liquid forming the liquid film L falls down before the transport into the drying chamber 32, the liquid still remains in a minute part of a fine pattern. By replacing the remaining liquid with a supercritical fluid and then drying the fluid, for example, it becomes possible to dry the substrate S while preventing collapse of the pattern. This method allows reduction in the amount of liquid to be brought into the drying chamber 32.

The foregoing reversion is performed while the hand 345 is retreated to a position sufficiently below the transfer zone Zt. More specifically, the height of the hand 345 is set in such a manner as to prevent the tip part 345 and the substrate S held thereon to be reversed from entering the floating zone Zt during the course of reversion. This setting may be made by making a distance in the Z direction between the upper surface Sa of the substrate S immediately before the reversion and the lower end of the transfer zone Zt greater than the radius of the substrate S, for example. By doing so, the substrate S or the hand 345 is prevented from entering the transfer zone Zt during the course of reversion. This allows the dry transport robot 4 to enter the transfer zone Zt even during implementation of the reversion.

As long as the process of the reversion is such that the dry transport robot 4 is not to access the cleaning chamber 31 or the drying chamber 32 during implementation of the reversing process, it can be considered that preventing the tip part 345a and the substrate S to be reversed from projecting upward further than the upper end of the transfer zone Zt is enough in setting the height of the hand 345 during the reversion. This avoids interference with the dry transport robot 4 by the wet transport robot 34, at least during movement of the dry transport robot 4 in the X direction.

In addition to the drying process of drying a substrate using a supercritical fluid described above, process involving the foregoing reversion may be performed in a case requiring reversion of the substrate for processing the both sides of the substrate, for example. The foregoing configuration is also preferably applicable to such process.

Further, according to the forgoing embodiment, the cleaning chamber 31 as the “first chamber” executes the cleaning process using a cleaning liquid, and the drying chamber 32 as the “second chamber” executes the drying process using a supercritical fluid. However, these processes are not the only processes to which the present invention is to be applied. Specifically, the present invention is applicable to transport of a substrate during implementations of various types of processes of processing the substrate sequentially in two or more chambers. In particular, the present invention is applied preferably to a process requiring transport of the substrate in a wet state between chambers. The types of chemical substances used in the processes are not limited to those described above but may be determined freely.

As the specific embodiment has been illustrated and described above, in the substrate processing apparatus according to the present invention, the first transport unit may include the horizontal movement mechanism that moves the first movement mechanism horizontally while the first movement mechanism locates the first holding member at a position above the transfer zone, for example. In this configuration, moving the first movement mechanism horizontally while holding a substrate with the first holding member allows the substrate to move largely in the horizontal direction. In this case, the first holding member still moves over the transfer zone to be prevented from affecting the operation of the second transport unit.

Furthermore, in this case, the first chamber and the second chamber to receive the substrate transferred from the first chamber may be configured as one processing unit and a plurality of the processing units may be provided, one second holding member may be provided for each of the processing units, and one first holding member may be provided for a plurality of the processing units. In this configuration, the dedicated second holding member is used for transfer of the substrate from the first chamber to the second chamber in each of the processing units, making it possible to make a rapid shift from a process in the first chamber to a process in the second chamber. On the other hand, the first holding member common between the processing units is used for incoming transport of an unprocessed substrate from the outside and outgoing transport of a processed substrate to the outside, thereby encouraging size reduction of the apparatus.

As another example, the second transport unit may be configured to transport the substrate in a horizontal posture to the second chamber while a liquid film formed in the first chamber is provided on the upper surface of the substrate, and the first transport unit may be configured to transport the substrate before formation of the liquid film into the first chamber and transport the substrate after removal of the liquid film out from the second chamber. This configuration allows the first holding member and the second holding member to be used separately between holding of the substrate with the liquid film and holding of the substrate without the liquid film. Even if liquid drops from the substrate held by the second holding member, locating the first holding member above the transfer zone still avoids adherence of the liquid to the first holding member or to the substrate held by the first holding member.

Furthermore, in this case, the first transport unit may include a plurality of the first holding members for holding the substrate before formation of the liquid film and for holding the substrate after removal of the liquid film. In this configuration, the substrate before being processed and the substrate after being processed are held by the different first holding members, making it possible to resolve a trouble caused if a foreign object on the unprocessed substrate adheres to the processed substrate, for example.

As another example, a drying process of removing the liquid film from the substrate and drying the substrate may be performed in internal space of the second chamber. For example, the drying process using a supercritical fluid may be performed in the internal space. In this configuration, the substrate is transported between the chambers with the liquid film formed on its surface and subjected to the drying process in the second chamber. This avoids exposure of the surface of the substrate to an atmosphere in the transport space during transport of the substrate.

As another example, the second transport unit may include a reversing mechanism that turns the second holding member holding the substrate upside down after the substrate with the liquid film is transported out from the first chamber and before the substrate is transported into the second chamber. In this configuration, the substrate is reversed from front to back, thereby allowing removal of the liquid film from the front surface of the substrate or implementation of a process on the back surface in the second chamber, for example.

As another example, the first opening at a side surface of the first chamber and the second opening at a side surface of the second chamber may be formed at the same height in such a manner as to face each other across the transport space. In this configuration, transfer of the substrate from the first chamber to the second chamber using the second transport unit can be realized by means of movement in the horizontal direction simply. In particular, in the presence of the liquid film on the substrate, this facilitates retention of the liquid film during the transfer.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

### INDUSTRIAL APPLICABILITY

This invention is generally applicable for a substrate processing apparatus in which a substrate is transported into multiple chambers by using multiple transport mechanisms.

### REFERENCE SIGNS

1 substrate processing apparatus
3 processing unit
4 dry transport robot (first transport unit)
5 control unit (controller)
31 cleaning chamber (first chamber)
32 drying chamber (second chamber)
34 wet transport robot (second transport unit)
311 opening (first opening)
321 opening (second opening)
342 hand (second holding member)
346 hand driving mechanism (second movement mechanism)
347 elevating mechanism (second movement mechanism)
349 reversing mechanism
421, 422 hand (first holding member)
476 hand driving mechanism (first movement mechanism)
477 elevating mechanism (first movement mechanism)
479 traveling mechanism (horizontal movement mechanism)
S substrate
S1, S2 internal space
S3 transport space
Zt transfer zone

1. A substrate processing apparatus, comprising:
a first chamber which has an internal space capable of storing a substrate as a process target and a first opening for putting the substrate into and taking the substrate out from the internal space;
a second chamber which has an internal space capable of storing the substrate and a second opening for putting the substrate into and taking the substrate out from the internal space;
a first transport unit which has a first holding member for holding the substrate and a first movement mechanism arranged above the first holding member, the first movement mechanism moving the first holding member to transport the substrate into the first chamber through the first opening and to transport the substrate out from the second chamber through the second opening; and
a second transport unit which has a second holding member for holding the substrate and a second movement mechanism arranged below the second holding member, the second movement mechanism moving the second holding member and transferring the substrate from the first chamber to the second chamber by transporting the substrate out from the first chamber through the first opening and transporting the substrate into the second chamber through the second opening, wherein:
the first opening and the second opening are formed bordering a transport space where the second transport unit is arranged;
the first movement mechanism locates the first holding member above a transfer zone when the second transport unit accesses the first opening or the second opening; and
the second movement mechanism locates the second holding member below the transfer zone when the first transport unit accesses the first opening or the second opening,
where the transfer zone is defined as a space out of the transport space in which the second holding member and the substrate pass through during transfer of the substrate by the second transport unit from the first chamber to the second chamber.

2. A substrate processing apparatus comprising:
a first chamber which has an internal space capable of storing a substrate as a process target and a first opening for putting the substrate into and taking the substrate out from the internal space;
a second chamber which has an internal space capable of storing the substrate and a second opening for putting the substrate into and taking the substrate out from the internal space;
a first transport unit which has a first holding member for holding the substrate and a first movement mechanism arranged above the first holding member, the first movement mechanism moving the first holding member to transport the substrate into the first chamber through the first opening and to transport the substrate out from the second chamber through the second opening;
a second transport unit which has a second holding member for holding the substrate and a second movement mechanism arranged below the second holding member, the second movement mechanism moving the second holding member and transferring the substrate from the first chamber to the second chamber by transporting the substrate out from the first chamber through the first opening and transporting the substrate into the second chamber through the second opening; and
a controller which controls the first transport unit and the second transport unit, wherein:
the first opening and the second opening are formed bordering a transport space where the second transport unit is arranged;
the first movement mechanism locates the first holding member above a transfer zone when the second transport unit accesses the first opening or the second opening; and
the controller restricts entry of the first holding member into a transfer zone when the second transport unit accesses the first opening or the second opening, and restricts entry of the second holding member into the transfer zone when the first transport unit accesses the first opening or the second opening,
where the transfer zone is defined as a space out of the transport space in which the second holding member and the substrate pass through during transfer of the substrate by the second transport unit from the first chamber to the second chamber.

3. The substrate processing apparatus according to claim 1, wherein
the first transport unit includes a horizontal movement mechanism which moves the first movement mechanism horizontally while the first movement mechanism locates the first holding member at a position above the transfer zone.

4. The substrate processing apparatus according to claim 3, further comprising a plurality of the processing units each of which includes a first chamber and a second chamber to receive the substrate transferred from the first chamber, wherein
one second holding member is provided for each of the processing units and one first holding member is provided for a plurality of the processing units.

5. The substrate processing apparatus according to claim 1, wherein
the second transport unit transports the substrate in a horizontal posture to the second chamber while a liquid film formed on an upper surface of the substrate in the first chamber, and
the first transport unit transports the substrate into the first chamber before formation of the liquid film and transports the substrate out from the second chamber after removal of the liquid film.

6. The substrate processing apparatus according to claim 5, wherein the first transport unit includes a plurality of the first holding members for holding the substrate before formation of the liquid film and for holding the substrate after removal of the liquid film respectively.

7. The substrate processing apparatus according to claim 5, wherein a drying process of removing the liquid film from the substrate and drying the substrate is executed in the internal space of the second chamber.

8. The substrate processing apparatus according to claim 7, wherein the drying process using a supercritical fluid is executed in the internal space.

9. The substrate processing apparatus according to claim 5, wherein the second transport unit includes a reversing mechanism which turns the second holding member holding the substrate upside down after the substrate with the liquid film is transported out from the first chamber and before the substrate is transported into the second chamber.

10. The substrate processing apparatus according to claim 1, wherein
the first opening at a side surface of the first chamber and the second opening at a side surface of the second chamber are formed at a same height in such a manner as to face each other across the transport space.

11. The substrate processing apparatus according to claim 2, wherein
the first transport unit includes a horizontal movement mechanism which moves the first movement mechanism horizontally while the first movement mechanism locates the first holding member at a position above the transfer zone.

12. The substrate processing apparatus according to claim 11, further comprising a plurality of the processing units each of which includes a first chamber and a second chamber to receive the substrate transferred from the first chamber, wherein
one second holding member is provided for each of the processing units and one first holding member is provided for a plurality of the processing units.

13. The substrate processing apparatus according to claim 2, wherein
the second transport unit transports the substrate in a horizontal posture to the second chamber while a liquid film formed on an upper surface of the substrate in the first chamber, and
the first transport unit transports the substrate into the first chamber before formation of the liquid film and transports the substrate out from the second chamber after removal of the liquid film.

14. The substrate processing apparatus according to claim 13, wherein the first transport unit includes a plurality of the first holding members for holding the substrate before formation of the liquid film and for holding the substrate after removal of the liquid film respectively.

15. The substrate processing apparatus according to claim 13, wherein a drying process of removing the liquid film from the substrate and drying the substrate is executed in the internal space of the second chamber.

16. The substrate processing apparatus according to claim 15, wherein the drying process using a supercritical fluid is executed in the internal space.

17. The substrate processing apparatus according to claim 13, wherein the second transport unit includes a reversing mechanism which turns the second holding member holding the substrate upside down after the substrate with the liquid film is transported out from the first chamber and before the substrate is transported into the second chamber.

18. The substrate processing apparatus according to claim 2, wherein
the first opening at a side surface of the first chamber and the second opening at a side surface of the second chamber are formed at a same height in such a manner as to face each other across the transport space.
